(19) United States
(12) Patent Application Publication
(10) Pub. No.: US 2014/0312880 A1
(43) Pub. Date: Oct. 23, 2014

(54) WIRELESS LAMP POWER SUPPLY DETECTION SYSTEM AND METHOD

(71) Applicant: KONINKLIJKE PHILIPS N.V., EINDHOVEN (NL)

(72) Inventors: Harald Josef Günther Radermacher, Aachen (DE); Georg Sauerländer, Aachen (DE)

(21) Appl. No.: 14/358,298

(22) PCT Filed: Nov. 2, 2012
(86) PCT No.: PCT/IB2012/056104

§ 371 Date: May 15, 2014

Related U.S. Application Data
(60) Provisional application No. 61/560,446, filed on Nov. 16, 2011.

(51) Int. Cl. G01R 31/40; G01R 31/44

(52) U.S. Cl. CPC G01R 31/40; G01R 31/44
USPC 324/76.11

(57) ABSTRACT

A wireless lamp detection system (20, 20′) is provided to wirelessly determine the topology of a lighting system (1) or the type of the power supply (3). The detection system (20, 20′) comprises a probe device (21, 21′) having at least a measurement probe (22), adapted for wireless coupling to a lamp (2) to provide a probe signal, corresponding to at least one physical parameter of said lamp power supply (3). A processing unit (29, 29′) is provided, connected with said probe device (21, 21′) to receive said probe signal and configured to determine a type oflamp power supply (3) from said probe signal.

### TECHNICAL FIELD

The present invention relates to the field of lighting and in particular to a wireless lamp power supply detection system and a corresponding method of wireless lamp power supply detection.

### BACKGROUND ART

In the field of lighting, conserving energy gained in significance for the design and operation of lighting systems, in particular for general room and office lighting applications. Although energy conservation efforts have been made for quite some time, the recent sharp increase in the cost of energy and furthermore novel official regulations have let to a strong need in solutions to decrease the energy consumed for lighting. Accordingly, retrofit lamps have been developed, serving this need.

A type of recently available lamps to retrofit common incandescent, fluorescent or halogen lamps use light emitting diodes (LEDs). Such LED retrofit lamps typically exhibit a substantially decreased power consumption compared with the lamps to be replaced and in addition a substantially increased lifetime.

While the decreased power consumption of LEDs in general is advantageous for conserving energy, this further results in differing electrical characteristics with respect to the lamp to be replaced. In some applications however, the installed power supply requires certain electrical load characteristics to be met to allow proper operation. One example of such application is a typical 12V halogen lighting system comprising a corresponding power supply for mains connection.

Since a change of the already installed power supply is not always possible and in any case leads to increased cost, retrofit lamps have been developed, which are adapted for particular types of lighting system topologies and/or power supplies. Such lamps may comprise electrical circuitry to allow proper operation and to enhance the efficiency as well as the dimming performance when employed in a respective lighting system with a specific type of power supply. Accordingly, it is necessary to select a suitable type of retrofit lamp in accordance with the respective lighting system topology and power supply installed.

However, in typical installation scenarios, for example in an office building, most of the wiring of the lighting system and in addition also the power supply may be installed hidden, such as in a suspended ceiling or in a dry wall. Accordingly, it is difficult to obtain information on the specifications of the lighting system and in particular on the specific type of power supply installed, rendering the task of choosing a compatible type of retrofit lamp tedious and time-consuming.

Accordingly, it is an object of the present invention to provide means to determine the electrical specifications of a lighting system in an easy and efficient way to reduce the overall time and cost needed for a retrofit process.

### DISCLOSURE OF INVENTION

The object is solved by a wireless lamp power supply detection system according to claims 1 and 12 and a method of wireless lamp power supply detection according to claim 15. The dependent claims relate to preferred embodiments of the invention.

The basic idea of the first aspect of the invention is to determine a type of power supply of a lamp by wireless coupling of a measurement probe to said lamp and processing a probe signal, obtained by said measurement probe. The determined type may then be used to select a suitable retrofit lamp. The second aspect of the invention allows to determine, whether two lamps are connected to a common power supply. This may be advantageous for a user to obtain information of the topology of the installed lighting system.

Both aspects of the present invention are based on the recognition of the present inventors that a typical lamp during operation, i.e. when supplied with an operating current by the respectively connected power supply, emits a signal, representing characteristic physical effects or artifacts allowing to determine physical/electrical parameters of a power supply by suitable processing.

The inventive system thus advantageously allows determining the type of power supply and/or the topology of the lighting system without requiring direct access to the power supply of the lighting system. In addition, advantageously no electrical access to the lamp supply wires is necessary either, which although conceivable, in practice typically is difficult. For example, the lamp may be hidden behind a glass cover or installed in a high ceiling. Furthermore, during use the lamp may be very hot and depending on the type of lamp fixture, even holding rings may have to be removed that might be covered with paint or dust, requiring cleaning or reworking. Of course, during replacement of the existing lamp with the LED lamp, some or all of these steps are required anyway. But then, the suitable lamp already has to be available, so that a determination of a suitable type needs to be conducted in advance. The wireless power supply detection system according to the invention avoids at least some steps of this tedious process and allows determining the type of power supply and/or the topology of the lighting system easily, providing a fast and cost-efficient retrofit process.

According to the first aspect of the invention, a wireless lamp supply power detection system is provided with a probe device having at least a measurement probe, adapted for wireless coupling to a lamp to provide a probe signal. The probe signal corresponds to at least one physical and/or electrical parameter of a lamp power supply. The system further comprises a processing unit, connected with said probe device to receive said probe signal and configured to determine a type of said lamp power supply from said probe signal.

As discussed above, the inventive wireless lamp supply detection system allows determining a type of a lamp power supply wireless, i.e. without a conductive connection to the respective power supply or the lamp.

In the context of the present invention, the term “lamp power supply” or “power supply” may refer to any type of electric or electronic circuitry, adapted to provide electrical power to the respective lamp at least during operation. The power supply thus is electrically connected to the lamp at least in an operational mode to provide operating power to the lamp. For example, the respective power supply may comprise a suitable transformer, electronic power converter, a dimming unit and/or any other type of suitable circuitry, connected with mains or a battery. Certainly, the power supply may be arranged to provide power to more than one lamp.

Preferably, the power supply is adapted to provide an alternating current (AC) to the lamp, i.e. an AC power supply. Most preferably, the power supply is a 12V power supply, such as present in typical halogen lighting systems. Particularly preferred, the power supply is adapted for mains connection.

As discussed above, the probe device according to the invention comprises at least said one measurement probe, which is adapted for wireless coupling to the lamp. Accordingly, the measurement probe during operation provides the probe signal, which corresponds to at least one physical parameter of the lamp power supply. For example, the probe signal may correspond to the voltage, current, frequency, provided by the lamp power supply to the lamp during operation and may additionally or alternatively comprise information on waveform, start- and end-point of oscillation as well as change of any of these parameters over time or loading phase.

The measurement probe according to the invention may be adapted for wireless coupling to any suitable type of lamp. In particular, the probe may be adapted for coupling to an incandescent or halogen lamp. Although the inventive system is adapted for wireless coupling, the system—although preferred for reasons of portability—does not necessarily need to be battery operated, but may have a connection to a suitable power supply, e.g. mains, to allow the above operation.

The wireless lamp power supply detection system according to the invention further comprises the processing unit as discussed in the preceding. The processing unit is connected with the probe device and the measurement probe respectively, to receive the probe signal over any suitable connection, such as a wired or wireless, digital or analogue connection.

The processing unit further is configured to determine a type of said lamp power supply from the probe signal, for example by analyzing the waveform or envelope of the probe signal for a characteristic pattern, for the presence of a defined frequency component or for defined amplitude changes. The determination certainly depends on the respective type of lighting system and power supply employed.

In the present context, the term “type of lamp power supply” may refer to one or more parameters, characterizing the respective power supply at least in part. In a first embodiment, the determination may thus provide information on the specific type of power supply used, for example the presence of an electronic switching type or so-called “magnetic” power supply. In a more advanced embodiment, the manufacturer and/or model of the power supply may be determined. Detailed embodiments of the operation of said processing unit are discussed in the following.

The processing unit may comprise any suitable electric or electronic circuitry to allow the above determination, e.g. discrete or integrated circuitry. Preferably, the processing unit comprises a microprocessor or computing unit, having a suitable programming, e.g. for pattern recognition.

As discussed above, the probe device comprises a measurement probe, adapted for wireless coupling to the lamp. The measurement probe may be of any suitable type for providing the probe signal, which corresponds to at least one physical parameter of the lamp power supply. To provide the probe signal, the measurement probe may thus be considered a transducing device, i.e. a device to transfer a type of energy to another type.

The at least one measurement probe may for example be adapted for optical coupling to the lamp, i.e. to determine said at least one physical parameter from the light, emitted by the lamp during operation. The measurement probe in this case may comprise one or more optical detectors, such as photodiodes. The processing unit in this case may be adapted to detect the color of the emitted light to obtain information of the voltage, supplied by the power supply to the lamp.

Alternatively or additionally, the measurement probe may be adapted for acoustic coupling to the lamp. According to the present example, the measurement probe may comprise one or more acoustic pickups or microphones. The type of power supply in this case may be determined from a characteristic noise pattern or frequency of the lamp during operation. For example, incandescent or halogen lamps produce a chirping noise when operated with a electronic switching type power supply or a dimming unit. Accordingly, the presence of such types of power supply can be determined in case an appropriate frequency signal is detected.

Alternatively or additionally and according to a preferred embodiment, the measurement probe is a near-field probe. The measurement probe in this case is adapted to determine the at least one electrical parameter of the lamp power supply from an electric and/or magnetic field, emitted by the lamp during operation. The present embodiment is particularly advantageous since the determination of a near-field parameter decreases the susceptibility to interference, allowing a more reliable determination of the type of power supply. The near-field probe may be of any suitable type, e.g. a capacitive or inductive probe.

Most preferably, the measurement probe is an inductive probe. Here, the probe signal typically corresponds to the operating current, provided to the lamp by the lamp power supply during operation.

While any type of inductive probe, such as e.g. a hall sensor or pickup-coil, may be used in the present case of a wireless coupling to the lamp, the inductive probe preferably should be adapted to the filament of the respective type of lamp to allow receiving a lample signal, even in case the lamp is hidden behind a glass cover. In particular, the inductive probe may preferably comprise a coil having a suitable shape and/or core material, adapted to the respective filament of the lamp. Alternatively or additionally, the inductive probe may comprise one or more movable and/or rotatable coils to properly receive the magnetic field, emitted by the lamp. Furthermore, the inductive probe may alternatively or additionally comprise multiple coils with differing orientation and/or sensitivity frequency ranges.

According to a further preferred embodiment, the inductive probe comprises at least one electrical coil having an elongated shape. The present embodiment is particularly advantageous for the use with typical halogen lamps and allows a further enhanced coupling of the probe to the filament of the lamp for the determination of the at least one electrical parameter of the lamp power supply.

The coil according to the present embodiment may be considered a linear-type coil, extending along a longitudinal axis. The coil thus provides a defined spatial sensitivity pattern. Preferably, the coil comprises a ferrite core, arranged along the longitudinal axis of the coil to further enhance the wireless coupling.

To provide an easy measurement of the probe signal even in case the respective lamp is installed in a ceiling of a room, the probe device preferably comprises an elongated remote measurement member having a measurement end and a handle end, where said handle end being arranged opposite to said measurement end on a longitudinal axis and said measurement probe being coupled with the measurement end of said remote measurement member.

The remote measurement member may be of any suitable type and shape, e.g. having a cylindrical shape. The handle end should be adapted to allow being securely held by a user. To provide a further simplified transport and storage of the system, the measurement member preferably is retractable, i.e. allows a variation in its length.

As discussed above, the determination of the type of power supply provides information of one or more parameters of said power supply, characterizing the respective power supply at least in part.

According to a further preferred embodiment, the processing unit comprises at least a frequency detector, configured to receive said probe signal, so that the processing unit may determine said type of lamp power supply from the determined frequency.

Preferably, the frequency detector is configured to detect a high-frequency component from said probe signal, so that the processing unit determines an electronic type power supply in case said high-frequency component is detected.

An electronic type of power supply, which is also referred to as switching or switching-mode power supply or transformer, typically comprises a switching circuit for providing a high-frequency oscillation. Due to this, a relatively small transformer can be used, which is cost effective and allows a small form factor. Depending on the respective type of electronic power supply, the high-frequency oscillation may be enveloped by the (sinusoidal) mains voltage. However, since the high-frequency oscillation is provided at the output of the power supply and thus to the lamp, in particular an LED retrofit lamp is required to comprise a corresponding high-frequency rectifier circuit to be compatible with such electronic type of power supply.

In contrast thereto, the frequency of the output of a common “magnetic” type of power supply, i.e. comprising a transformer, substantially corresponds to the mains frequency, thus allowing to use a LED retrofit lamp having a more inexpensive rectifier circuit. The same applies in case the power supply does not comprise a transformer, such as e.g. in mains voltage halogen lighting systems.

According to the present embodiment, the presence of an electronic type of power supply is determined by detecting a high-frequency component from the wirelessly obtained probe signal. In case the high-frequency component is not present, the processing unit may preferably be adapted to determine a magnetic type of power supply.

The high-frequency component typically corresponds to the high-frequency oscillation of the electronic type power supply and in general shows a frequency of more than 100 Hz. Preferably, the high-frequency component of the probe signal shows a frequency of 20 kHz-200 kHz.

To determine said high-frequency component, the frequency detector may be configured to compare the probe signal with a frequency threshold, so that an electronic type power supply is determined in case the high-frequency component higher than said frequency threshold. Most preferably, the frequency detector is configured to filter the probe signal to remove low-frequency components, e.g. using a high-pass filter having a cut of frequency of 10 kHz. Then the amplitude of said filtered probe signal may be determined and compared with a voltage threshold, e.g. using a suitable comparator circuit. The processing unit determines an electronic type of lamp power supply in case the amplitude of said filtered probe signal is higher than said threshold. In the respective other case, a magnetic type of the power supply is assumed.

Additionally or alternatively the low-frequency amplitude can be measured, e.g. using a low-pass filter with a cut-off frequency of 1 kHz. Then, the signal amplitude of the high-frequency component and the determined low-frequency amplitude are compared, so that an electronic type of lamp power supply is determined in case the amplitude of the high-frequency component is higher than the low-frequency amplitude.

As will be apparent, the voltage threshold certainly depends on the setup of the respective lighting system and the power supply as well as the type of measurement probe. Therefore, the threshold should be chosen according to the application.

Additionally or alternatively and according to a further preferred embodiment of the invention, the processing unit comprises an envelope signal detector, configured to receive said probe signal, so that the processing unit determines said type of lamp power supply from the determined envelope signal.

As discussed above, the sinusoidal mains voltage may form an envelope of the high-frequency oscillation when the power supply is adapted for mains operation. Accordingly, it is possible to determine a mains operated type of power supply, for example by determining whether an envelope signal is present in said probe signal. Such determination may e.g. be provided by low-pass filtering of the probe signal.

Alternatively or additionally, the processing unit may be further configured to determine a dimming type of lamp power supply from said envelope signal. According to the present embodiment, the processing unit is configured to determine, whether said power supply is adapted for dimming operation, i.e. comprises a dimming unit.

The present embodiment allows a further enhanced selection of a suitable LED retrofit lamp, since some types of retrofit lamps may be incompatible with a dimming operation. For example, a retrofit lamp may require a certain minimum average power for a stable operation, so that dimming would cause an instable operation and thus flicker.

The presence of a dimming unit may be determined e.g. by detecting an edge in said envelope signal, i.e. a steep rise or decline in each half-cycle of the envelope signal, which is characteristic for phase-cut dimmers.

In addition, the processing unit may further preferably be adapted to determine, whether said dimming type power supply is of “trailing-edge” or “leading-edge” type, i.e. whether a trailing-edge or leading-edge dimming unit is present. In both types of dimmers, a part of the sinusoidal envelope signal is cut out either from the end part of each half-cycle (trailing-edge dimmer) or from the front part of each half-cycle (leading-edge dimmer).

To determine the specific type of dimming unit of said power supply, the processing unit preferably determines the phase angle of the envelope signal, i.e. the time interval in each half-cycle of the envelope signal, in which the voltage is substantially 0 Volt or in which the voltage is substantially (e.g. below 5%) of the peak voltage of the envelope signal, i.e. the voltage, expected at the peak of the corresponding mains voltage. To determine the correct peak voltage, the respective dimming unit should be set to a firing angle so that the load is activated during peak, e.g. a leading-edge dimming unit is set to a firing angle below or equal to 90° and a trailing-edge dimming unit should be set to a phase-angle higher than 90°.

In case a leading-edge dimming unit is used, the startup point would be shifted towards later points in time. Accordingly, a longer period of no voltage, i.e. the envelope signal being substantially 0 Volt, followed by a sudden start of the voltage, following the envelope of the basically sinusoidal mains voltage, is an indication for a leading-edge dimming unit. On the other hand, a quite short period of no voltage, followed by an early startup and finally a sudden drop of the voltage to substantially 0 Volt, is an indication for a trailing-edge dimming unit. The above evaluation of the envelope signal may e.g. be conducted by a suitable microprocessor or computing device, comprised in the processing unit.

Alternatively or additionally to the above-described operation and in accordance with a further preferred embodiment, the detection system may comprise storage means, which storage means comprise power supply information. The processing unit according to the present embodiment may be configured to compare said probe signal with the power supply information to determine the type of lamp power supply.

According to the present embodiment, the type of power supply is determined from a comparison between said probe signal and the power supply information. While the present embodiment may be used in conjunction with the above, it is certainly conceivable to employ the present embodiment separately from the above operation of a frequency or envelope detection to provide a cost-efficient setup.

As mentioned above, the storage means comprises power supply information, which, in terms of the present explanation is understood as comprising one or more electrical parameters of a plurality of different types of power supplies, allowing to individually characterize said power supplies. The power supply information may therefore e.g. correspond to a database of power supply parameters to allow an efficient identification of different types of power supplies.

The power supply information may preferably comprise information regarding the phase angle, the start-up voltage, i.e. the voltage present at the end of each phase angle interval, frequency, stability of frequency, characteristic waveform of the probe signal or the envelope signal and/or any other parameter, which may form a characteristic profile of a certain type of a power supply. In addition, artifacts during power-up of the power supply, i.e. upon connection with power, can be taken into account for determining the exact type of power supply (brand, model no.).

The storage means may be of any suitable type, and may comprise one or more memory devices, such as typical RAM, ROM or FLASH memory. Certainly, the storage means may comprise other type of memory, such as optical or magnetic memory, e.g. one or more hard drives. Although the storage means preferably are formed integrally with said processing unit, the storage means may be provided externally, e.g. remote from said processing unit. For example, an embodiment is conceivable, in which the processing unit is configured for communication with a remote server, comprising said storage means.

To compare the probe signal with the power supply information, the processing unit may be adapted with a signal analysis circuit, arranged to match the probe signal with the power supply information or “profile” of the respective power supply.

Upon determination of the respective type of power supply, the processing unit may provide a user with information on the determined type. Therefore, it is preferred that a display device, such as an LCD display, is connected with said processing unit to indicate the determined power supply type. The user may then decide upon a suitable type of retrofit lamp.

Alternatively or additionally, the storage means may further comprise retrofit lamp type information, associated with said power supply information, so that said processing unit upon determination of said type of lamp power supply determines one or more associated lamp types. According to the present example, a retrofit lamp type, suitable for use with the determined power supply is directly indicated to the user, providing a further simplified retrofit process. Preferably, the associated one or more lamp types are indicated to the user on the above mentioned display device.

While the system described above provides a determination of a type of a power supply, in some applications it may be sufficient or additionally required to determine, whether two or more lamps are connected to the same, i.e. a common power supply.

Therefore and according to a second aspect of the present invention, a wireless lamp power supply detection system is provided, comprising a first probe device having at least a measurement probe, adapted for wireless coupling to a first lamp to provide a probe signal, corresponding to at least one physical/electrical parameter of a lamp power supply of said first lamp. Furthermore, a processing unit is provided, connected with said probe device to receive said first probe signal and configured to compare said first probe signal with a second probe signal of a second lamp to determine, whether said first and second lamp are connected to a common lamp power supply.

As described above, the basic idea of the detection system according to the second aspect is to determine, whether two lamps are connected to a common power supply by comparing of first and second probe signals of a first and second lamp, respectively. Certainly, it may be conceivable to determine and compare more than two probe signals.

The present aspect may be advantageous to determine the number of lamps and hence the present load of the respective power supply and thus allows a conclusion of the power rating per power supply. Furthermore, it is possible to determine whether the lamps are connected to the same phase of a 2- or 3-phase mains supply, which can be important for providing a flicker free illumination.

To compare said first and second probe signal, the processing unit may comprise suitable signal analysis circuitry or a suitable microprocessor with an according programming. Certainly, the two probe signals may slightly differ from each other even in case the two lamps are connected to a common power supply due to differences in the wiring of the two lamps or measurement errors. Therefore, the processing unit should be adapted to compare the signals based on an approximation algorithm.

To obtain said second probe signal, various procedures are conceivable. For example, the processing unit may be configured for subsequent measurement of said first and second probe signals. Accordingly, it is preferred that the processing unit is further configured to receive said first probe signal from said probe device in a first measurement step and to store information corresponding to said first probe signal. Then, the second probe signal of said second lamp is received from said probe device in a second measurement step to allow comparing said signals.

The stored information may be of any kind to allow comparing said signals and determine a common power supply with a sufficient accuracy. However, it is not necessary to store the first probe signal entirely. Instead it may be possible to store an approximation of said first probe signal, e.g. using pulse code modulation, to allow a comparison with a sufficient accuracy. To allow storing the information, the processing unit may comprise a suitable memory, such as RAM, ROM or FLASH memory.

While the above embodiment of a subsequent measurement requires a user to move the measurement probe from the first lamp to the second lamp, it may certainly be conceivable to provide a second probe device to allow a simultaneous operation.

Therefore and according to a further preferred embodiment, the system further comprises a second probe device having a second measurement probe. The second measurement probe is adapted for wireless coupling to said second lamp to provide said second probe signal to the processing unit.

The present embodiment further enhances the operability of the system and allows an even more time-efficient retrofit process.

The setup of the system and in particular the measurement probe and the processing unit according to the second aspect of the present invention, described in the preceding, may in addition to the above explanations correspond to one or more embodiments discussed in connection with the above discussion of the first aspect of the present invention.

Furthermore an embodiment is conceivable, combining the detection system according to said first aspect with the corresponding setup of the detection system according to said second aspect.

### BRIEF DESCRIPTION OF THE DRAWINGS

These and other aspects, features and advantages of the present invention will be apparent from and elucidated with reference to the description of preferred embodiments in conjunction with the enclosed figures, in which:

FIG. 1 shows an exemplary 12V halogen lighting system in a schematic view;

FIG. 2 shows an embodiment of a wireless lamp power supply detection system according to a first aspect of the invention;

FIG. 3 shows the embodiment of FIG. 2 in use with a lighting system according to FIG. 1;

FIG. 4a shows a schematic graph of an exemplary probe signal in case of an electronic type power supply;

FIG. 4b shows a schematic graph of a further exemplary probe signal in case of a dimming type power supply;

FIG. 5 shows a flow diagram of the operation of the embodiment according to FIG. 2;

FIG. 6 shows a further embodiment of a wireless lamp power supply detection system according to a second aspect of the invention.

### DESCRIPTION OF EMBODIMENTS

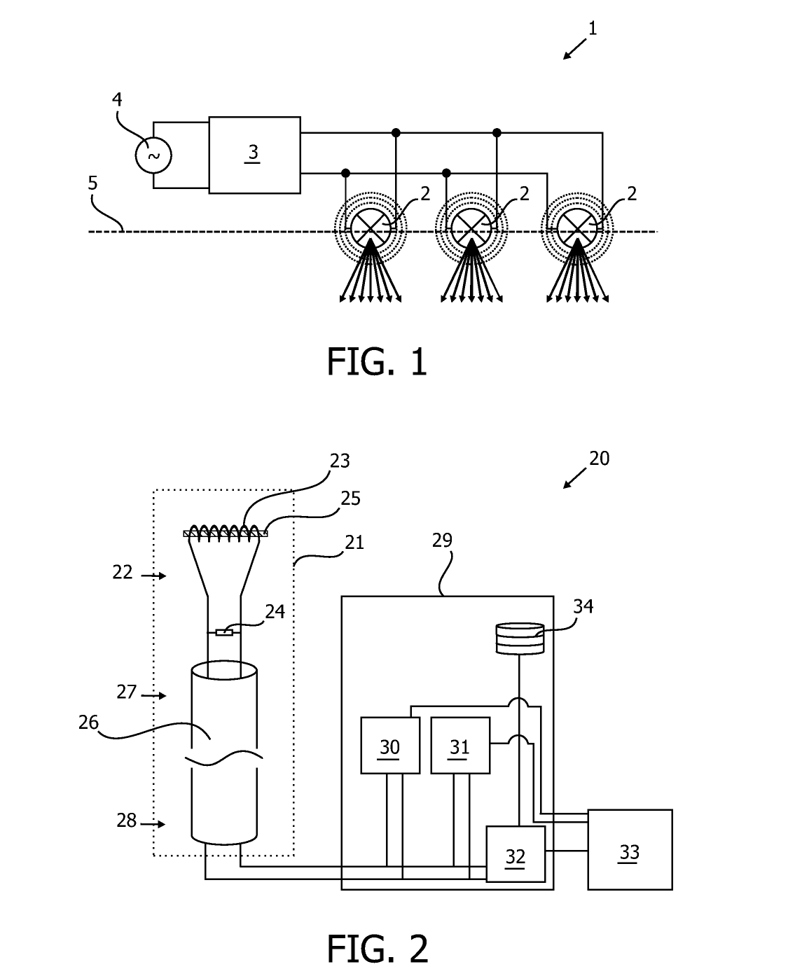

FIG. 1 shows an exemplary 12 V AC halogen lighting system 1 in a schematic view. The lighting system 1 comprises three lamps 2, which according to the present example are typical 12 V halogen lamps. Each of the lamps 2 is connected to a lamp power supply 3 which provides the lamps 2 with power during operation. The power supply 3 is connected with mains 4, e.g. a 110 V/220 V mains line. Accordingly, the power supply 3 provides transformation of the mains voltage to a voltage of 12 V AC, needed to operate the lamps 2.

The components of the lighting system 1 according to FIG. 1 are installed in a suspended ceiling 5 as indicated by the broken line in the figure. While it is certainly possible to access the lamps 2, e.g. for a replacement, no direct access to the power supply 3 is given. While this arrangement is advantageous to hide most of the components of the lighting system 1, e.g. for aesthetic reasons, the setup typically allows no direct access to the power supply 3 and thus it is difficult to obtain information with regard to the type of power supply 3 or the detailed topology of the lighting system 1. Both aspects however may be of interest to a user or installer, for example in case of a planned retrofit of the lamps 2 with LED lamps.

During operation, the lamps 2 emit light as indicated by the arrows in FIG. 1. Due to the presence of the filament, which basically has the form of a coil, the lamps 2 in addition emit a magnetic field, indicated by the dotted lines in the figure, the field strength of which substantially corresponds to the current through the respective lamp 2.

FIG. 2 shows an embodiment of a wireless lamp power supply detection system 20 according to a first aspect of the invention. The detection system 20 allows to measure the magnetic field and thus the current through the respective lamp 2 to advantageously allow a determination of the type of the lamp power supply 3. The determination of the type according to the present example includes the determination of a magnetic or electronic type of power supply 3, the determination of a dimming operation of said power supply 3 and the brand and model no. of said power supply 3.

The detection system 20 comprises a probe device 21 having a measurement probe 22, which according to the present example comprises a coil 23 ballasted by resistor 24. The coil 23 is of elongated shape and comprises a ferrite or iron core 25 to enhance the coupling of the measurement probe 22 with the field emitted by lamp 2 when the measurement probe 22 is brought in proximity to the respective lamp 2, i.e. closer than 20 cm to the lamp 2. The probe device 21 further comprises an elongated remote measuring member, i.e. a measuring pole 26, having a measurement end 27 to which the measurement probe 22 is mounted and a handle end 28, which is formed with a handle (not shown) to be held by a user. The measuring pole 26 furthermore guides the electrical connections between the measurement probe 22 and a processing unit 29. Furthermore and although not shown in FIG. 2, the length of the measuring pole 26 is variable to allow easy storage of the device.

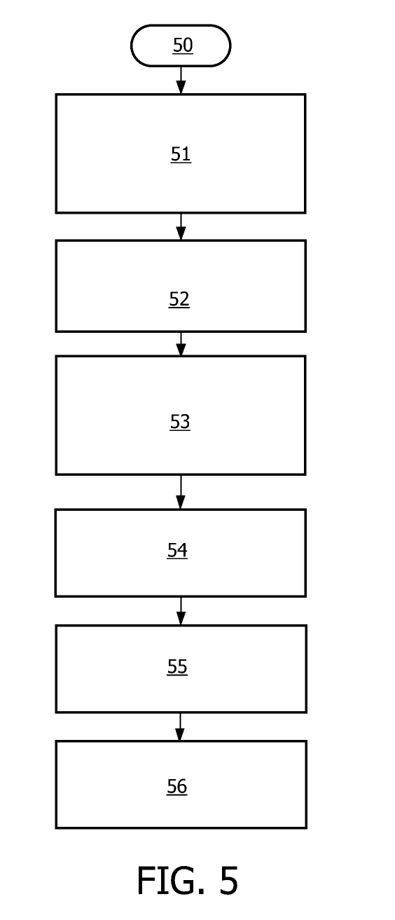

During operation, the measurement probe 22 provides a probe signal when brought into proximity with one of the lamps 2. The voltage of the probe signal corresponds to the current through the lamp 2 and is received by processing unit 29 and provided to a frequency detector 30, envelope signal detector 31 and signal analyzer 32. The output of each of the before-mentioned components is connected with a display device 33, which according to the present example comprises an LCD display to show the result of the determination process to a user. Furthermore, storage means 34 are provided, which according to the present example comprises flash memory and contains a power supply information database. While the frequency detector 30 and the envelope signal detector 31 allow a determination of the general type or class of the power supply 3, the signal analyzer 32 in combination with the power supply information database on storage means 34 allows an exact determination of the type of power supply 3 of the lighting system 1, i.e. the manufacturer and exact model number of the power supply 3, as will be explained in the following with reference to the flow diagram of FIG. 5.

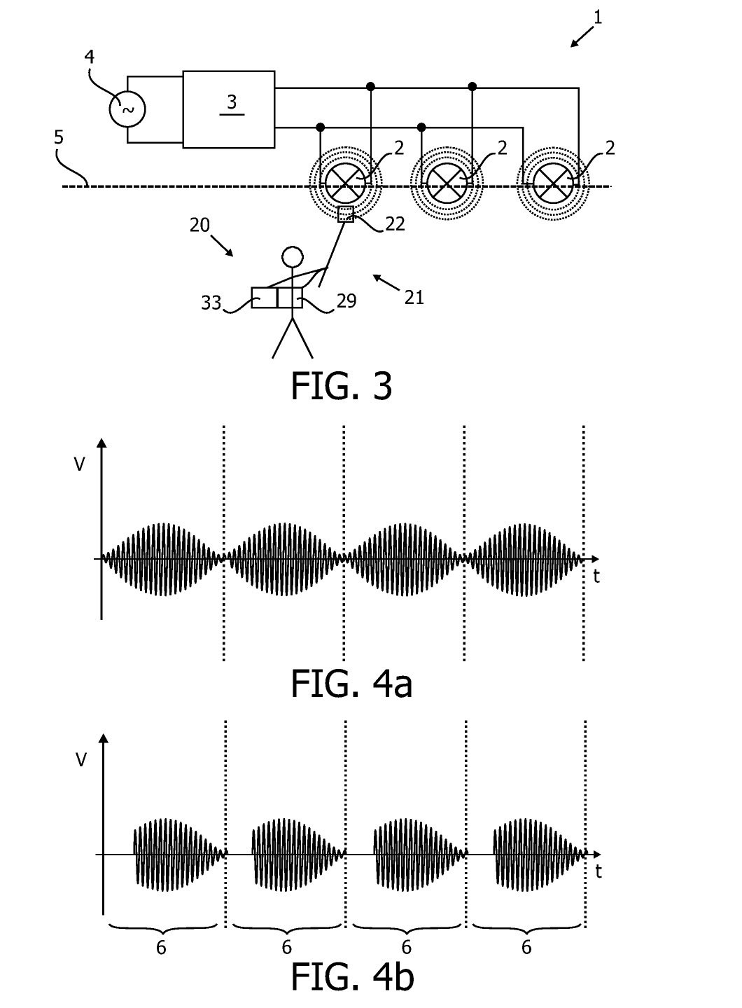

The determination of the type of power supply 3 is initiated in step 50 by the user bringing the measurement probe 22 in close proximity to one of the lamps 2, as shown in FIG. 3. An according probe signal is then acquired in step 51. Certainly, the acquisition of the probe signal requires the lighting system 1 to the operational, i.e. lamps 2 need to be provided with power by power supply 3. In step 52, the probe signal is provided to the frequency detector 30, envelope signal detector 31 and signal analyzer 32. Subsequently in step 53, the frequency detector 30 determines, whether the probe signal comprises a high-frequency component, according to the present example a signal component of higher than 20 kHz. The frequency detector 30 is accordingly equipped with a high-pass filter (not shown) to provide the filtered probe signal to a threshold detector. The threshold detector provides a high output signal in case a voltage threshold is met, which then corresponds to a high-frequency component being determined. The presence of said high-frequency component in the probe signal is taken as an indication of an electronic type power supply, i.e. a switching mode power supply, since here due to the high-frequency operation of the switching converter, the output signal, provided to the lamps 2 will inherently comprise said high-frequency component.

The voltage threshold may be user adjustable. Alternatively, the measurement probe 22 may be placed in a large distance from the lamp 2 to measure a high-frequency background level of the ambience as a reference. When the measurement probe 22 is placed in the detection distance, as discussed above closer than 20 cm to one of the lamps 2, the presence of the high-frequency component may be indicated when the received filtered probe filter exceeds twice the high-frequency background level. The alternative (reference) measurement can be made at the same position but with the lamp 2 not operating, i.e. with the power supply 3 switched off. A further input determining the threshold is the presence and setting of a dimming unit. In case an average filter is used on the HF-signal, the relative duration in response to the dimmer setting can be taken into account, too.

An example of a corresponding exemplary probe signal in case of an electronic type power supply 3 is shown in FIG. 4a. The schematic graph of FIG. 4a shows the high-frequency oscillation of the switching converter, i.e. the high-frequency component, present in the probe signal. It is noted, that according to FIG. 4a, the high-frequency oscillation is enveloped by the sinusoidal mains current.

Parallel to the operation of frequency detector 30, envelope signal detector 31 determines whether the power supply 3 is of dimming type, i.e. comprises a phase-cut dimming unit. In this case, a part of the sinusoidal envelope signal, provided by the power supply to the lamps 2 is cut-out either from the end part in each half-cycle 6, which corresponds to a trailing-edge dimmer, or from the front part of each half-cycle 6 which corresponds to a leading-edge dimmer. A corresponding example of a probe signal in case of a leading-edge type dimmer is shown in FIG. 4b. As can be seen from the figure, the front part of the sinusoidal envelope is cut-out in each half-cycle 6.

The envelope signal detector 31 comprises a microprocessor, having a suitable programming for signal analysis. The microprocessor extracts the envelope signal from the probe signal and then determines whether a front or end part in each half-cycle 6 of the sinusoidal envelope signal is cut-out to determine a trailing-edge or a leading-edge dimmer. This is conducted by determining the phase angle, i.e. the period of no voltage provided to the lamp. In case a leading-edge dimmer is used, a longer period of no voltage followed by a sudden start of the voltage and a basically sinusoidal envelope is be determined. A quite short period of no voltage, followed by an early start-up and sudden drop of the voltage to zero volt, is an indication for a trailing-edge dimming unit. Certainly, it is possible that the power supply 3 comprises no dimming unit, in this case, the probe signal corresponds basically to the schematic graph of FIG. 4a.

Once it is determined, whether an electronic type power supply 3 is present using frequency detector 30 and it is determined, whether a dimming type supply 3 is present by envelope detector 31 the result of the determinations is provided to display device 33 in step 54. The display device 33 shows the result of the determination to the user. The user may then for example decide to choose a specific type of lamp to retrofit the lighting system 1, such as a specific type of LED retrofit lamp once this is complete, the user may initiate a detailed signal analysis if needed, to obtain the exact manufacturer and model no. of said power supply 3.

Accordingly in step 55, the signal analyzer 32 compares the probe signal with the power supply information database, comprises in storage means 34. The database comprises information on the phase angle, frequency, stability of frequency, waveform of signal and envelope, forming characteristic profiles of multiple power supplies 3, which profiles are stored together with the brand name and exact model number of the respective power supply 3. For comparing the probe signal with the power supply information database, the signal analyzer 32 comprises a microprocessor with signal analysis software, arranged to match the probe signal with said profiles. In case a match is found in the database, the signal analyzer 32 provides the display device 33 in step 56 with the brand name and the model number of the power supply, which is then shown to the user.

It is noted, that in addition to the above, the storage means 34 may optionally further comprise a lamp type information database associated with said power supply information database. Accordingly in this case, the signal analyzer 32 in addition to providing the brand name and model number of the determined power supply 3 may provide one or more suitable types of retrofit lamps to the display device 33, so that the user may directly see which types of lamps are suitable for operation with the respectively determined power supply 3.

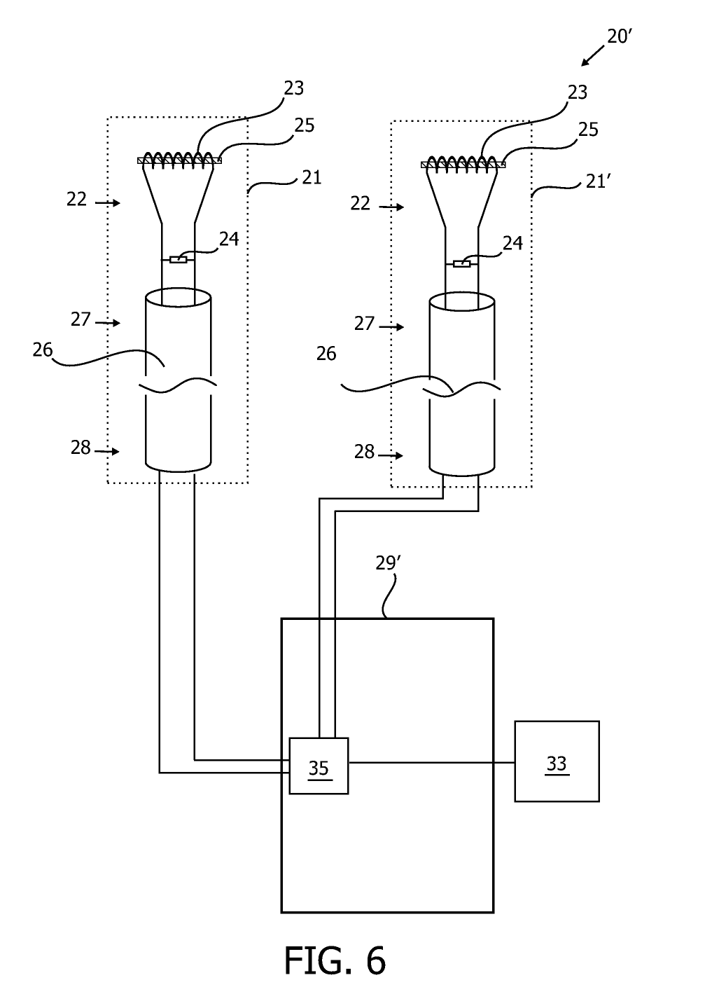

FIG. 6 shows a second embodiment of a wireless lamp power supply detection system 20′ according to a second aspect of the present invention. The present embodiment corresponds to the embodiment of FIG. 2 with the exception of processing unit 29′ and a second probe device 21′.

The present embodiment allows to provide a first and a second probe signal of corresponding first and second of lamps 2. According to the present example, processing unit 29′ comprises a comparator device 35 to determine, whether the first and second probe signals of the probe devices 21, 21′ substantially correspond to each other to determine, whether the first and second of lamps 2 are connected to the same common power supply 3. The present embodiment may be particular advantageous to determine whether the lamps 2 are connected to the same power supply and thus the same phase of a 2- or 3-phase mains supply, which can be important for providing a flicker-free illumination, in particular for commercial applications.

The comparator device 35 comprises a microprocessor with a suitable programming for signal analysis. The microprocessor is adapted to compare first and second probe signals based on an approximation algorithm, so that it is to possible safely determine a common power supply 3, even in case the probe signals slightly differ from each other, e.g. due to measurement errors. The result of the determination is then again shown on the LCD display of display device 33.

While the above embodiment according to FIG. 6 has been explained as an alternative to the setup and operation of the embodiment according to FIG. 2, it is certainly conceivable to operate the invention in a combined embodiment, thus allowing to determine the type of the power supply 3 and in addition, whether two of the lamps 2 are connected to a common power supply.

Other variations to the disclosed embodiments can be understood and effected by those skilled in the art and practicing the claimed invention from a study of the drawings, the disclosure and the appended claims.

For example, it is possible to operate the invention in an embodiment, in which:
the detection system 20, 20′ comprises two or more probe devices 21, 21′,
the measurement probe 22, instead of or additionally to comprising coil 23, comprises a capacitive, acoustic and/or optical pickup,
the storage means 34 being provided externally or on a remote server and/or
in the embodiment of FIG. 6, instead of providing two probe devices 21, 21′,
   providing a single probe device 21, where said processing unit 29′ being adapted for subsequent measurement of said first and second probe signals of said first and second of lamps 2.

In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting the scope.

1. Wireless lamp power supply detection system, comprising
a probe device having at least a measurement probe, adapted for wireless coupling to a lamp to provide a probe signal, corresponding to at least one physical parameter of a lamp power supply of said lamp and
a processing unit, connected with said probe device to receive said probe signal and configured to determine a type of said lamp power supply from said probe signal,
wherein said measurement probe is an inductive probe.

2. Wireless lamp power supply detection system according to claim 1, wherein said measurement probe is a near-field probe.

3. (canceled)

4. Wireless lamp power supply detection system according to claim 1, wherein said probe device comprises an elongated remote measurement member having a measurement end and a handle end, said measurement end being arranged opposite of said handle end on a longitudinal axis of said measurement member, said measurement probe being coupled with the measurement end.

5. Wireless lamp power supply detection system according to claim 4, wherein said processing unit comprises at least a frequency detector, configured to receive said probe signal, so that said processing unit determines said type of lamp power supply from a detected frequency.

6. Wireless lamp power supply detection system according to claim 5, wherein said frequency detector is configured to detect a high-frequency component from said probe signal and said processing unit is configured to determine an electronic type power supply in case said high-frequency component is detected.

7. Wireless lamp power supply detection system according to claim 6, wherein said processing unit comprises at least an envelope signal detector, configured to receive said probe signal, so that the processing unit determines said type of lamp power supply from a determined envelope signal.

8. Wireless lamp power supply detection system according to claim 7, wherein said processing unit is further configured to determine a dimming type lamp power supply from said envelope signal.

9. Wireless lamp power supply detection system according to claim 8, wherein said system further comprises storage means, which storage means comprise power supply information and said processing unit being configured to compare said probe signal with said power supply information to determine said type of lamp power supply.

10. Wireless lamp power supply detection system according to claim 9, wherein said storage means further comprises retrofit lamp type information, associated with said power supply information, so that said processing unit upon determination of said type of lamp power supply determines one or more associated lamp types.

11. Wireless lamp power supply detection system according to claim 10, further comprising a display device, connected with said processing unit to indicate said determined type of lamp power supply and/or said one or more associated lamp types.

12. Wireless lamp power supply detection system according to claim 1, wherein
the processing unit, is configured to compare said received probe signal of said lamp with a second received probe signal of a second lamp to determine, whether said lamp and said second lamp are connected to a common lamp power supply.

13. Wireless lamp power supply detection system according to claim 12, wherein said processing unit is further configured
to receive said first probe signal from said probe device in a first measurement step,
to store information, corresponding to said first probe signal,
to receive said second probe signal from said probe device in a second measurement step and then to compare said first and second probe signals.

14. Wireless lamp power supply detection system according to claim 12, further comprising a second probe device having a second measurement probe, adapted for wireless coupling to said second lamp to provide said second probe signal.

15. A method of wireless lamp power supply detection, comprising a probe device having at least a measurement probe, wherein said measurement probe is an inductive probe, the method comprising:
wirelessly coupling said measurement probe to a lamp;
providing a probe signal, corresponding to at least one physical parameter of a lamp power supply of said lamp; and
determining a type of said lamp power supply from said probe signal.

16. The method according to claim 15, further comprising:
receiving said probe signal, using at least a frequency detector;
determining said type of lamp power supply from a detected frequency.

17. The method according to claim 16, further comprising:
detecting a high-frequency component from said probe signal; and
determining an electronic type power supply in case said high-frequency component is detected.

18. The method according to claim 17, further comprising:
receiving said probe signal, using at least an envelope signal detector;
determining said type of lamp power supply from a determined envelope signal;

19. The method according to claim 18, further comprising determining a dimming type lamp power supply from said envelope signal.
